(19) United States
(12) Patent Application Publication
(10) Pub. No.: US 2003/0008476 A1
(43) Pub. Date: Jan. 9, 2003

(54) Method of fabricating a wafer level package

(76) Inventors: Wen Hsu, Taipei City (TW); Chi-Hsing Hsu, Hsin Chuang City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/899,143

(22) Filed: Jul. 6, 2001

(51) Int. Cl. H01L 21/30; H01L 21/46; H01L 21/44; H01L 21/50; H01L 21/48

(52) U.S. Cl. 438/455; 438/456; 438/108

(57) ABSTRACT

The present invention provides a method of fabricating a wafer level package. A semiconductor wafer having a plurality of chips thereon is first provided. A substrate having an area smaller than that of the chip is installed on each chip. A plurality of wires are used to connect bonding pads of the chip to the substrate. An encapsulation is then used to sheathe all the wires. Finally, a plurality of solder balls are arranged on the surface of the substrate between the wires. A wafer level package is thus formed. A plurality of electronic package devices can be obtained after slicing the wafer level package. In the present invention, original manufacturing equipments still can be used. The packaged electronic package device has a size commensurate to the chip size so that it is compact and occupies less area. Moreover, it has good electronic properties.

### FIELD OF THE INVENTION

The present invention relates to a method of fabricating an integrated circuit (IC) package structure and, more particularly, to a method of fabricating a wafer level package.

### BACKGROUND OF THE INVENTION

Due to the progress of IC technology, the enhancement of levels and functions of electronic products tends toward multifunction, high speed, large capacity, high density, and light weight. To meet these requirements, in addition to the continual advance of IC fabrication technology, many novel packaging techniques and materials have been developed. The variations exhibited on the package look are multiple leads, thin forms, fine leads, and manifold lead shapes.

Please refer to FIGS. 1(a) to 1(e). For the prior art IC package devices such as the ball grid array (BGA) package, a printed circuit board (PCB) is used as an electronic package substrate 14. A wafer 10 is first sliced into a plurality of dies 12. A die 12 is glued on the upper surface of the substrate 14. A plurality of wires 16 are used to connect the substrate 14 and the die 12. An encapsulation 18 is used to sheathe the die 12 and the wires 16. Solder balls 20 on the bottom of the substrate 14 are used to electrically connect the die 12 to other electronic devices. Although the BGA package can provide more leads, it can't provide a structure of smaller volume because of the restriction of its outer size.

Moreover, in the above fabrication method, the packaging is performed one by one, thereby taking much time. Therefore, the throughput will be low. Additionally, in the above electronic package device, because the heat-dissipation path is too long, malfunction of the IC (Integrated Circuits) may occur. Moreover, because the electricity-conducting path is too long, noise may arise so as to influence the normal function of the chip.

The present invention aims to propose a method of fabricating a wafer level package to overcome the above disadvantages.

### SUMMARY OF THE INVENTION

The primary object of the present invention is to provide a method of fabricating a wafer level package, which method has high throughput and is suitable to mass production. The present invention can also provide a compact package structure whose size is commensurate to the chip size.

Another object of the present invention is to provide a method of fabricating a wafer level package so that original manufacturing equipments still can be used.

Yet another object of the present invention is to provide a method of fabricating a wafer level package with short electricity-conducting paths so that the electronic package device will not be easily interfered and thus has good electronic properties.

According to the present invention, a wafer having a plurality of chips is first provided. A first surface of a substrate is installed on each chip. The chip size is larger than that of the substrate. A plurality of wires are used to electrically connect bonding pads of the chip to a second surface of the substrate. An encapsulation is used to sheathe all the wires. Finally, a plurality of solder balls are arranged at the second surface of the substrate so as to electrically connect the chip to other electronic devices.

The various objects and advantages of the present invention will be more readily understood from the following detailed description when read in conjunction with the appended drawings, in which:

### BRIEF DESCRIPTION OF THE DRAWINGS:

FIGS. 1(a) to 1(e) show a prior art packaging method of the ball grid array package;

FIG. 2 is a diagram of an electronic package device according to an embodiment of the present invention;

FIGS. 3(a) to 3(e) show a packaging flow chart of the present invention;

FIG. 4 a diagram of an electronic package device according to another embodiment of the present invention; and

FIG. 5 is a diagram showing that a substrate matrix is directly installed on a wafer according to yet another embodiment of the present invention.

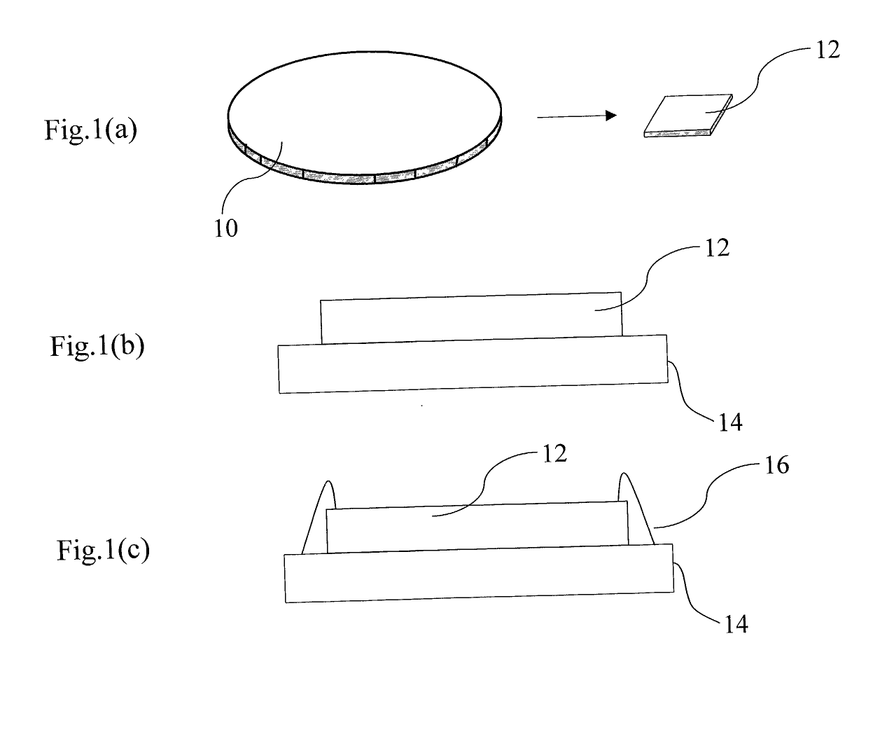

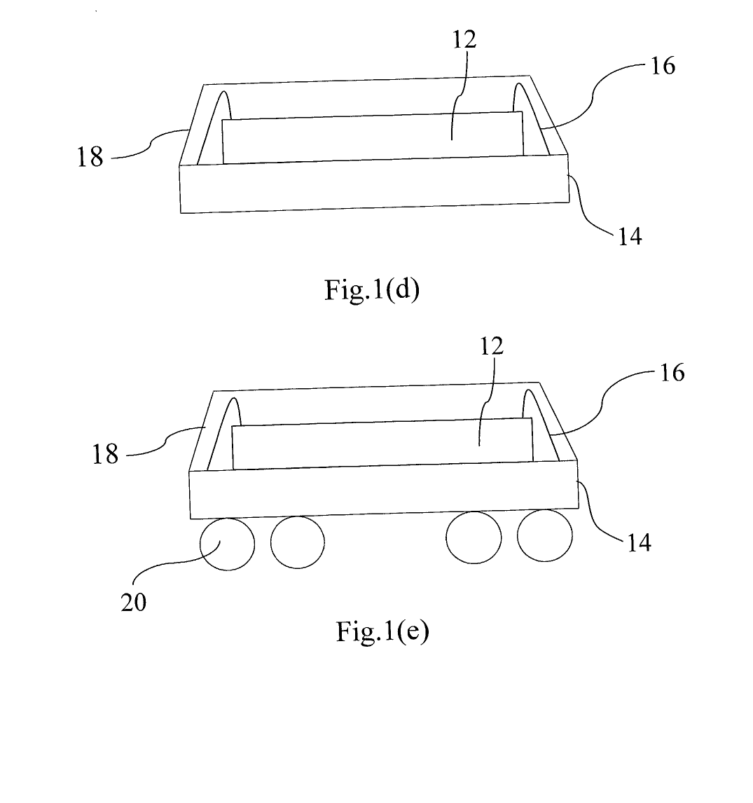

### DETAILED DESCRIPTION OF THE PREFERRED EMBODIMENTS

The present invention is characterized in that a plurality of chips preset on a semiconductor wafer are directly packaged to form a plurality of electronic package devices. The characteristic that the area of the substrate is smaller than the chip size is exploited to let the size of the packaged electronic device be commensurate to the chip size.

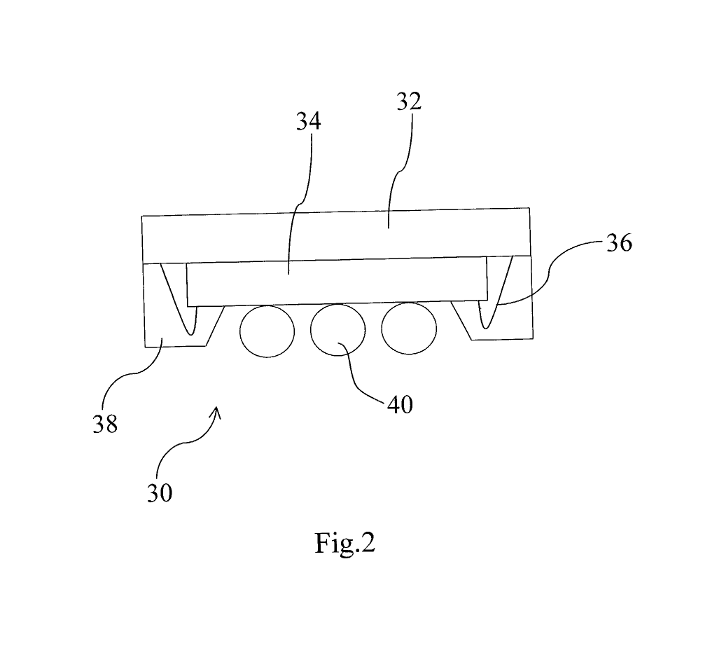

As shown in FIG. 2, an electronic package matrix is sliced into a plurality of electronic package devices, each electronic package device 30 being a chip 32 installed on a substrate 34. The substrate 34, generally being a PCB, has a first surface and a second surface. The size of the chip 32 is larger than the area of the substrate 34 so that the first surface of the substrate 34 can be glued on the chip 32. A plurality of wires 36 are used to electrically connect bonding pads on the chip 32 to the second surface of the substrate 34. An encapsulation 38 is used to sheathe all the wires 36 to provide protection. Finally, a plurality of solder balls 40 are arranged at the second surface of the substrate 34 so as to electrically connect the chip to other electronic devices.

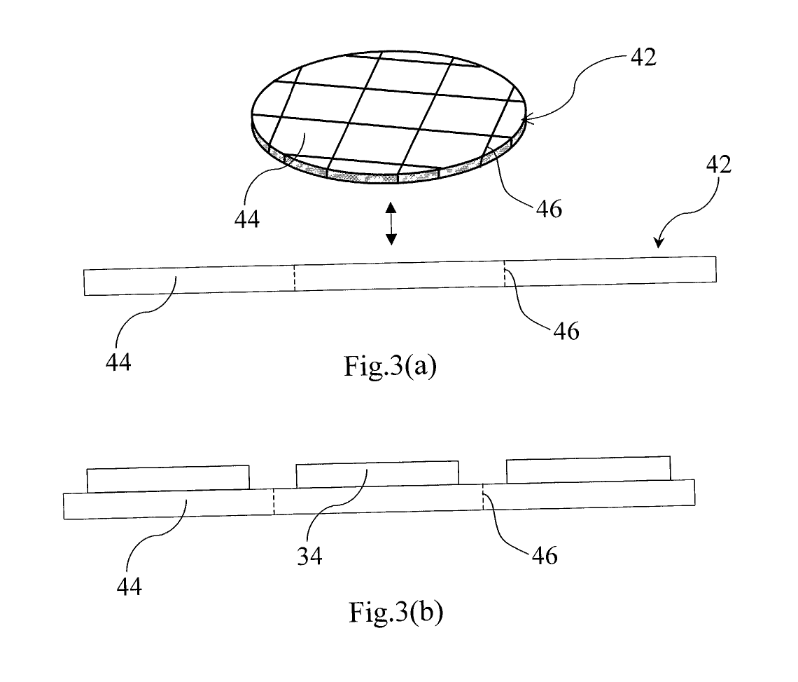

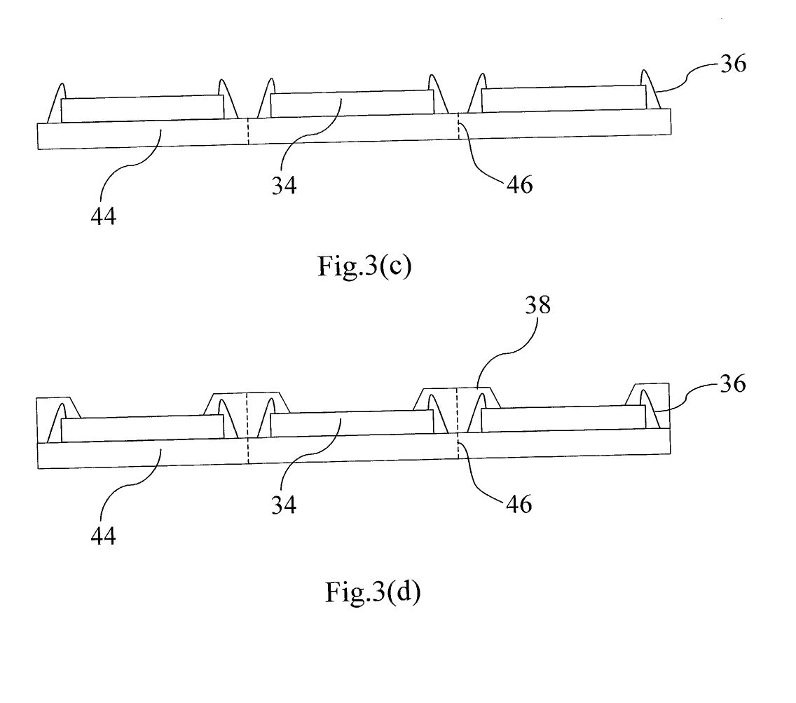

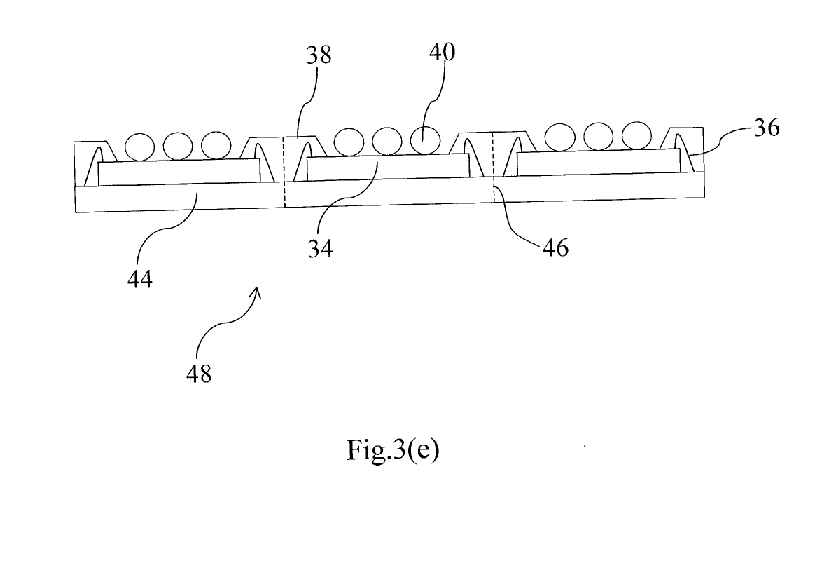

One embodiment of the present invention is shown in FIG. 3. A whole semiconductor wafer 42 having a plurality of chips 44 properly arranged thereon is provided. A sawing path 46 is provided between every two adjacent chips 44. A substrate 34 having an area smaller than that of the chip 44 is installed on each chip 44. The substrate 34 has a first surface and a second surface. The first surface of the substrate 34 is glued on the chip 44. A plurality of wires 36 are used to electrically connect bonding pads on the chip 44 to the second surface of the substrate 34 by means of wire bonding. An encapsulation 38 is used to sheathe all the wires 36 to provide protection. Next, a plurality of solder balls 40 are soldered to the second surface of the substrate 34. An electronic package matrix 48 is thus formed. Finally, the electronic package matrix 48 is cut along the sawing paths 46 to obtain a plurality of electronic package devices 30, as shown in FIG. 2.

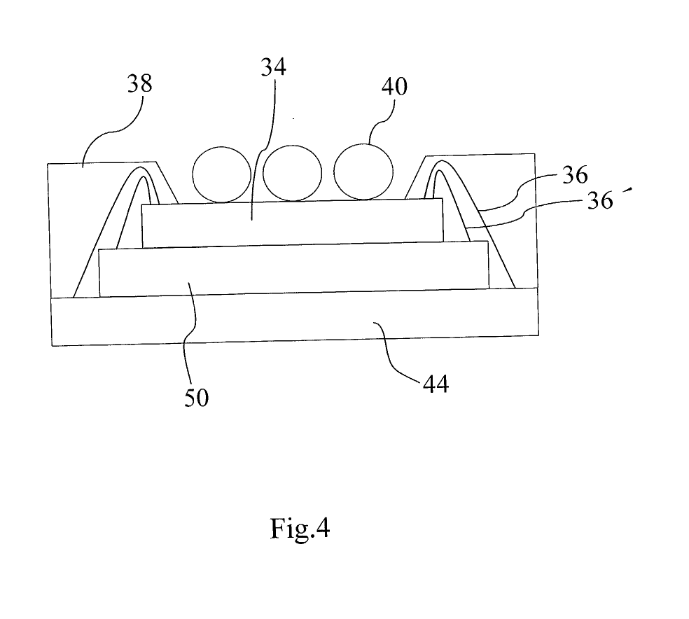

Except directly installing a substrate 34 having a smaller area on the surface of each chip 44 of the above semiconductor wafer 42, at least a chip 50 can be installed before installing the substrate 34, as shown in FIG. 4. A chip 50 of smaller size is glued on each chip 44, and a substrate 34 of even smaller size is then installed on the chip 50. Therefore, both the sizes of the chip 44 and the chip 50 are larger than that of the substrate 34. A plurality of wires 36 and 36′ are used to electrically connect the two chips 44 and 50 to the second surface of the substrate 34. An encapsulation 38 is used to sheathe all the wires 36 and 36′. An electronic package having stacked chips 44 and 50 is thus formed. Therefore, in the present invention, stacked chips can be installed on the substrate so as to increase the density and capacity of the electronic package device.

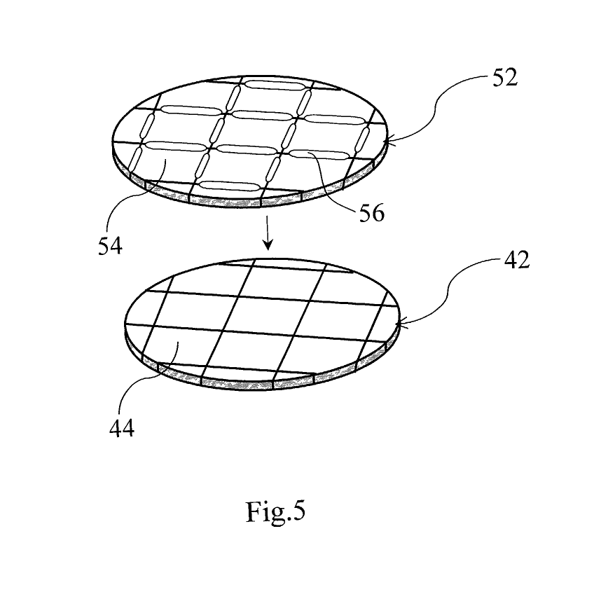

FIG. 5 shows yet another embodiment of the present invention. A substrate matrix 52 having a plurality of substrate units 54 is directly installed on the wafer 42. A first surface of each substrate unit 54 is installed on each chip 44. A slot 56 for wire bonding is formed between every two adjacent substrate units 54 of the substrate matrix 52 so that a plurality of wires can pass through the slot to connect the chip 44 to a second surface of the substrate unit 54. The installing ways of other structures are the same as those of the above packaging method and thus will not be further described.

To sum up, the present invention directly performs the operations of packaging and then slicing on a wafer. Less time needs to be taken so that the object of mass production can be achieved. Therefore, the throughput is higher. Moreover, original manufacture equipments can be used so that the production cost will not be increased. The area of the packaged electronic package device of wafer level package is commensurate to the chip size so that the electronic package device is compact. Furthermore, the electricity-conducting path in the present invention is shorter so that the electronic package device will not be easily interfered and thus has good electronic properties.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A method of fabricating a wafer level package, comprising the steps of:
providing a semiconductor wafer having a plurality of chips properly arranged thereon;
installing a substrate having an area smaller than that of said chip on each of said chips;
using a plurality of wires to electrically connect bonding pads of said chip to the other surface of said substrate;
sheathing said wires with an encapsulation; and
forming a plurality of solder balls on the surface of said substrate between said wires.

2. The method of fabricating a wafer level package as claimed in claim 1, wherein at least a chip can be installed before installing said substrate on each of said chips.

3. The method of fabricating a wafer level package as claimed in claim 1, wherein a substrate matrix can be directly installed on said wafer in said step of installing said substrate, said substrate matrix having a plurality of substrate units, each said substrate unit corresponding to one of said chip, a slot being formed between every two adjacent said substrate units to be passed through by said wires.
